(19) United States
(12) Patent Application Publication
(10) Pub. No.: US 2022/0223466 A1
(43) Pub. Date: Jul. 14, 2022

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: ChihCheng LIU, Hefei City (CN)

(73) Assignee: CHANGXIN MEMORY TECHNOLOGIES, INC., Hefei City (CN)

(21) Appl. No.: 17/449,808

(22) Filed: Oct. 2, 2021

Related U.S. Application Data
(63) Continuation of application No. PCT/CN2021/101938, filed on Jun. 24, 2021.

(30) Foreign Application Priority Data
Jan. 14, 2021 (CN) 202110047836.7

(51) Int. Cl. H01L 21/762

(52) U.S. Cl. CPC H01L 21/76229

(57) ABSTRACT

A semiconductor device includes: a semiconductor substrate provided therein with shallow trenches and active regions defined by the shallow trenches, the shallow trenches having, in a predetermined direction, first regions and second regions which are alternately arranged, a width of the first region being greater than a width of the second region; and a shallow trench isolation structure filled in the shallow trench, the shallow trench isolation structure at least including, in the first region, a first filling layer and a second filling layer which are sequentially arranged, wherein the second filling layer is configured as a low-K dielectric layer; in the second region, the shallow trench isolation structure at least including the first filling layer.

### CROSS-REFERENCE TO RELATED APPLICATIONS

This application is a continuation of International Patent Application No. PCT/CN2021/101938 filed on Jun. 24, 2021, which claims priority to Chinese Patent Application No. 202110047836.7 filed on Jan. 14, 2021. The above-referenced applications are hereby incorporated by reference in their entirety.

### BACKGROUND

With the high integration of semiconductors, more and more advanced manufacturing processes are applied to the semiconductor manufacturing process. With the evolution of Moore's Law to the 1×nm level, active regions are required to be more densely arranged.

### SUMMARY

The present disclosure relates generally to the field of semiconductor production, and more specifically to a semiconductor structure and a manufacturing method thereof.

Various embodiments of the present disclosure provide a semiconductor device, including: a semiconductor substrate provided therein with shallow trenches and active regions defined by the shallow trenches, the shallow trenches having, in a predetermined direction, first regions and second regions which are alternately arranged, a width of the first region being greater than a width of the second region; and a shallow trench isolation structure filled in the shallow trench, the shallow trench isolation structure at least including, in the first region, a first filling layer and a second filling layer which are sequentially arranged, wherein the second filling layer is configured as a low-K dielectric layer; in the second region, the shallow trench isolation structure at least including the first filling layer.

Various embodiments of the present disclosure further provide a manufacturing method of the semiconductor device as described above, including the following steps: providing a semiconductor substrate, the semiconductor substrate being provided therein with shallow trenches and active regions defined by the shallow trenches, the shallow trenches having, in a predetermined direction, first regions and second regions which are alternately arranged, a width of the first region being greater than a width of the second region; and forming a shallow trench isolation structure in the shallow trench, the shallow trench isolation structure at least including, in the first region, a first filling layer and a second filling layer which are sequentially arranged, wherein the second filling layer is configured as a low-K dielectric layer; in the second region, the shallow trench isolation structure at least including the first filling layer.

### BRIEF DESCRIPTION OF DRAWINGS

In order to more clearly illustrate the technical solutions in the embodiments of the present disclosure, the accompanying drawings required to be used in the description of the embodiments will be briefly introduced below. Apparently, the accompanying drawings in the following description merely show some embodiments of the present disclosure, and persons of ordinary skill in the art may still derive other drawings from these accompanying drawings without creative efforts.

FIG. 1 is a schematic distribution diagram of active regions and wordlines of a semiconductor device;

FIG. 2 is a schematic top view of a semiconductor device according to a first embodiment of the present disclosure;

FIG. 3 is a schematic cross-sectional view taken along line B-B in FIG. 2;

FIG. 4 is a schematic top view of a semiconductor device provided with wordlines;

FIG. 5 is a schematic cross-sectional view of a semiconductor device according to a second embodiment of the present disclosure;

FIG. 6 is a flowchart of steps of a manufacturing method of a semiconductor device according to an embodiment of the present disclosure;

FIG. 7A is a first schematic top view of a semiconductor structure in a step of a manufacturing method of a semiconductor device according to an embodiment of the present disclosure;

FIG. 7B is a first schematic cross-sectional view of a semiconductor structure in a step of a manufacturing method of a semiconductor device according to an embodiment of the present disclosure;

FIG. 7C is a second schematic cross-sectional view of a semiconductor structure in a step of a manufacturing method of a semiconductor device according to an embodiment of the present disclosure;

FIG. 7D is a third schematic cross-sectional view of a semiconductor structure in a step of a manufacturing method of a semiconductor device according to an embodiment of the present disclosure;

FIG. 7E is a fourth schematic cross-sectional view of a semiconductor structure in a step of a manufacturing method of a semiconductor device according to an embodiment of the present disclosure;

FIG. 7F is a fifth schematic cross-sectional view of a semiconductor structure in a step of a manufacturing method of a semiconductor device according to an embodiment of the present disclosure;

FIG. 7G is a second schematic top view of a semiconductor structure in a step of a manufacturing method of a semiconductor device according to an embodiment of the present disclosure; and

FIG. 7H is a sixth schematic cross-sectional view of a semiconductor structure in a step of a manufacturing method of a semiconductor device according to an embodiment of the present disclosure.

### DETAILED DESCRIPTION

In order to more clearly illustrate the objective, technical means and effects of the present disclosure, the present disclosure will be further elaborated below in conjunction with the accompanying drawings. It should be understood that embodiments described here are only a part of, not all the embodiments of the present disclosure and not intended to limit the present disclosure. All other embodiments obtained by a person of ordinary skill in the art based on the embodiments of the present disclosure without creative efforts shall fall within the protection scope of the present disclosure.

A novel 3*2 structure makes the layout of memory cells closer to the densest packing through the staggered arrangement of the active regions. However, all because of this staggered arrangement of active regions, a wordline (WL) will periodically pass through a region between two active regions in a set direction.

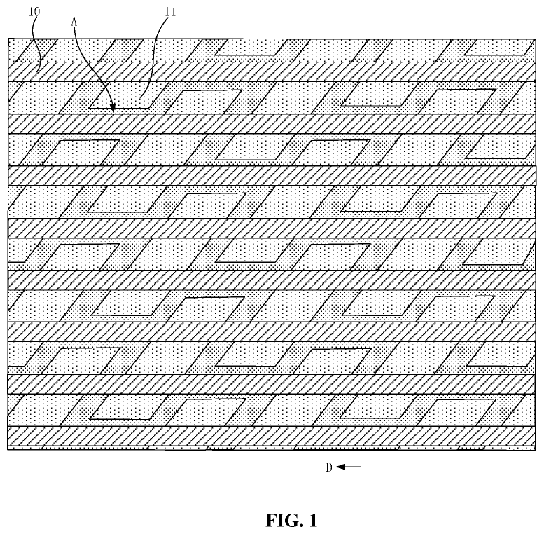

FIG. 1 is a schematic distribution diagram of active regions and wordlines in a semiconductor device. Referring to FIG. 1, in a set direction, Direction D (i.e., an extension direction of the wordline 10), the wordline 10 periodically passes through Region A between two active regions 11. The wordline passing through the Region A is called a passing wordline (Passing WL). As the arrangement density increases, a distance between the wordlines is getting smaller and smaller. When a wordline is activated, in addition to affecting the active region that it passes through, it will also induce the formation of a PN junction between this wordline and a deactivated wordline on an adjacent active region at the position (i.e., Region A) where the wordline passes, thus causing the generation of parasitic capacitance and further resulting in junction leakage and a reduction in product yield.

Various embodiments of the present disclosure can provide a novel semiconductor device to reduce or eliminate junction leakage and improve the yield of semiconductor devices.

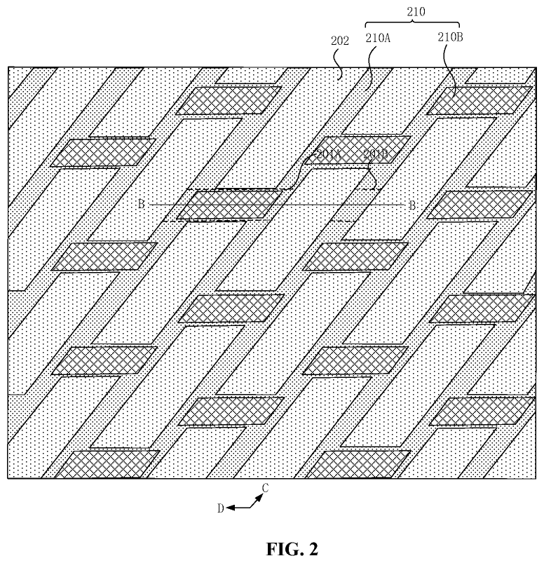

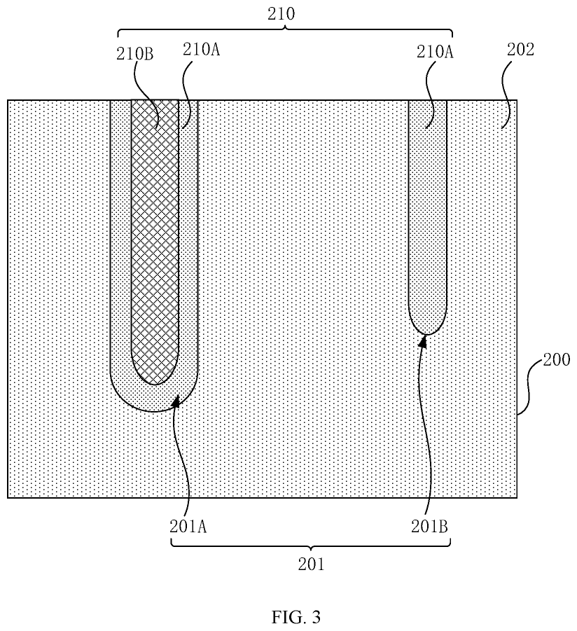

FIG. 2 is a schematic top view of a semiconductor device according to a first embodiment of the present disclosure, and FIG. 3 is a schematic cross-sectional view taken along line B-B in FIG. 2. Referring to FIGS. 2 and 3, the semiconductor device includes a semiconductor substrate 200 and a shallow trench isolation structure 210.

The semiconductor substrate 200 can be configured as a monocrystalline silicon substrate, a Ge substrate, a SiGe substrate, SOI, GOI, or the like. According to the actual requirements of the device, a suitable semiconductor material can be selected to form the semiconductor substrate 200 and it will not be limited here. In this embodiment, the semiconductor substrate 200 is configured as a monocrystalline silicon substrate.

The semiconductor substrate 200 has shallow trenches 201 and active regions 202 defined by the shallow trenches 201. In this embodiment, the shallow trenches 201 are formed in the semiconductor substrate 200 by photolithography and etching processes, and a region between the shallow trenches 201 serves as the active region 202. The active region 202 extends along a set direction, i.e., Direction C, that is, the active region 202 extends in the Direction C.

In a predetermined direction, the shallow trenches 201 have first regions 201A and second regions 201B which are alternately arranged, and a width of the first region 201A is greater than a width of the second region 201B. In FIG. 2, the first region 201A and the second region 201B are schematically encircled by dashed boxes.

The predetermined direction is Direction D as shown in FIG. 2. In the Direction D, between the two active regions 202 spaced apart, the shallow trench 201 has a larger width and serves as the first region 201A. Between two adjacent active regions 202, the shallow trench 201 has a smaller width and serves as the second region 201B. The predetermined direction is the extension direction of subsequently formed wordlines, and the wordlines periodically pass through the first region 201A, the active region 202, the second region 201B, and the active region 202. The wordline passing through the first region 201A serves as a passing wordline (Passing WL). The predetermined direction (Direction D) and the extension direction (Direction C) of the active region 202 form an inclined angle, and the inclined angle depends on a manufacturing process of the active region 202.

The shallow trench isolation structure 210 is filled in the shallow trench 201 to isolate the active region 202. In the first region 201A, the shallow trench isolation structure 210 at least includes a first filling layer 210A and a second filling layer 210B which are sequentially arranged, wherein the second filling layer 210B is configured as a low-K dielectric layer; in the second region 201B, the shallow trench isolation structure at least includes the first filling layer 210A.

In this embodiment, in the first region 201A, the shallow trench isolation structure 210 has two layers, wherein the first filling layer 210A covers the sidewalls of the shallow trench 201, and the second filling layer 210B covers the sidewalls of the first filling layer 210A and fills up the shallow trench 201; in the second region 201B, the shallow trench isolation structure 210 has one layer, and the first filling layer 210A covers the sidewalls of the shallow trench 201 and fills up the shallow trench.

Since the width of the first region 201A is greater than the width of the second region 201B, and after the first filling layer 210A is formed in the shallow trench, the shallow trench 201 in the first region 201A is not full filled, and thus the second filling layer 210B is further filled in the first region 201A.

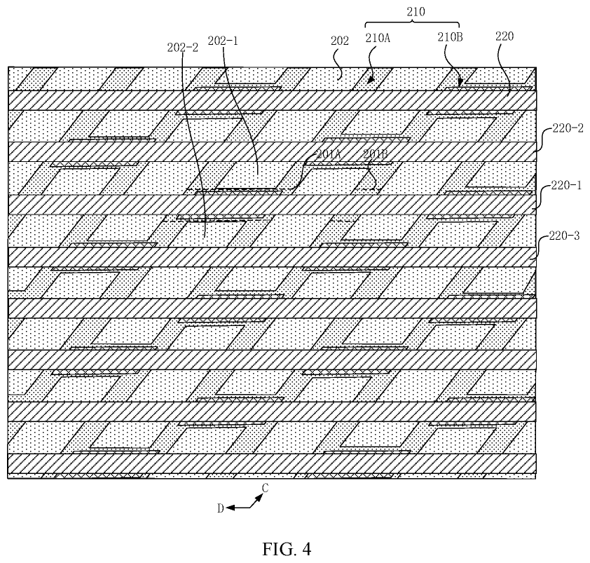

The second filling layer 210B is configured as a low-K dielectric layer, which can reduce the parasitic capacitance caused by the wordline, thus further reducing leakage current. Specifically, referring to FIG. 4 which is a schematic top view of a semiconductor device provided with wordlines. A plurality of wordlines 220 sequentially pass through the active region 202 and the shallow trench isolation structure 210 along the predetermined direction (Direction D), that is, the wordlines 220 sequentially pass through the first region 201A, the active region 202, the second region 201B, and the active region 202 periodically. In the first region 201A, due to the existence of the second filling layer 210B, when the wordline passing through the first region 201A is activated, the second filling layer 210B can have a good isolation effect and can prevent a case where electrons flow to the active region 202 due to the actuation of the wordline 220, thereby avoiding the generation of parasitic capacitance between the wordline 220 located in the first region 201A and an adjacent wordline which passes through the active region 202 and is not activated, avoiding the generation of leakage current, and greatly improving the electrical performance of the semiconductor device.

For example, further referring to FIG. 4, taking a wordline 220-1, a wordline 220-2, and a wordline 220-3 as an example, the wordline 220-1 extends in the Direction D and periodically passes through the first region 201A, an active region 202, the second region 201B, and the active region 202; the wordline 220-2 extends along the Direction D and periodically passes through the first region 201A, an active region 202, the second region 201B and the active region 202; the wordline 220-3 extends along the Direction D and periodically passes through the first region 201A, an active region 202, the second region 201B, and the active region 202; when the wordline 220-1 is activated but the word line 220-2 and the word line 220-3 are not activated, in the first region 201A, the second filling layer 210B can have a good isolation effect, and can prevent a case where electrons flow along the Direction C to the adjacent active region 202, such as the active region 202-1 and the active region 202-2 as shown in FIG. 4 due to the actuation of the wordline 220-1, thereby avoiding the generation of parasitic capacitance between the wordline 220-1 located in the first region 201A and wordlines 220-2 and 220-3 which pass through the active region 202-1 and the active region 220-2 and are not activated, avoiding the generation of leakage current, and also greatly improving the electrical performance of the semiconductor device.

Further, the dielectric constant of the second filling layer 201B is less than or equal to 4, for example, about 3. Compared with a material with a higher dielectric constant, such as silicon nitride and silicon oxide, the second filling layer 201B can have a good isolation effect, thereby avoiding the generation of parasitic capacitance and further avoiding the generation of leakage current. The second filling layer 201B can be made of a low-K dielectric material, such as phospho-silicate-glass (PSG), boro-phospho-silicate-glass (BPSG), and fluorine-doped phosphate glass (FSG).

Further, in the predetermined direction (Direction D), the width of the second filling layer 210B is less than the width of the first region 201A, and is greater than or equal to one third of the width of the first region 201A, to minimize the parasitic capacitance caused by the Passing WL while maintaining the electrical isolation performance of the shallow trench isolation structure, thereby reducing the leakage current.

Further, the first filling layer 210A is configured as an oxide layer, which may be determined according to a material of the semiconductor substrate 200. For example, in this embodiment, the semiconductor substrate 200 is configured as a monocrystalline silicon substrate, and then the first filling layer 210A is configured as a silicon oxide layer. In other embodiments of the present disclosure, the semiconductor substrate is configured as a Ge substrate and then the first filling layer 210A may be configured as a nitride layer.

In the semiconductor device of the present disclosure, the isolation effect of the second filling layer 210B (made of a low-K dielectric material) can be used for blocking the flow of electrons, thereby avoiding the generation of parasitic capacitance, avoiding the generation of leakage current, greatly improving the electrical performance of the semiconductor device, and also improving the yield of semiconductor devices.

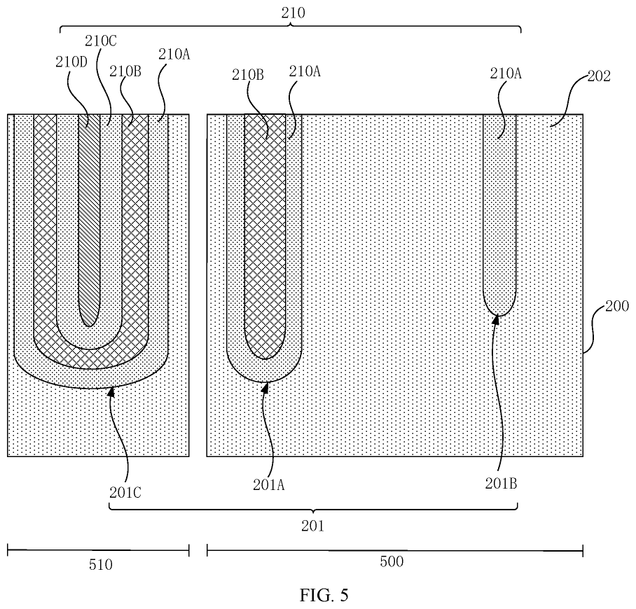

The present disclosure further provides a second embodiment of the semiconductor device. Referring to FIG. 5 which is a schematic cross-sectional view of a semiconductor device according to the second embodiment of the present application. This embodiment differs from the first embodiment in that, in this embodiment, the shallow trench 201 of the semiconductor device further includes a third region 201C. A width of the third region 201C is greater than the width of the first region 201A, and in the third region 201C, the shallow trench isolation structure 210 at least includes the first filling layer 210A, the second filling layer 210B, and a third filling layer 210C which are arranged sequentially. That is, in the third region 201C, the shallow trench isolation structure 210 includes at least three filling layers.

Since the width of the third region 201C is greater than the width of the first region 201B, and after the first filling layer 210A and the second filling layer 210B are formed in the shallow trench 210, the shallow trench 201 in the third region 201A is not full filled, and thus the third filling layer 210B needs to be configured to further fill the shallow trench 201.

Further, the third filling layer 201C can be configured as a nitride layer, for example, a silicon nitride layer. Since a thermal expansion coefficient of the nitride is close to a thermal expansion coefficient of the semiconductor substrate, the stress can be reduced in a high-temperature manufacturing process of other subsequent processes, and the performance of the semiconductor device can be improved.

Further, in this embodiment, since the width of the shallow trench 201 located in the third region 201C is quite different from the width of the shallow trench 201 located in the first region 201A, and after the third filling layer 210C is formed, in the third region 201C, the shallow trench isolation structure 210 further includes a fourth filling layer 210D. The fourth filling layer 210D covers the third filling layer 210C and fills up the shallow trench 201. The fourth filling layer 210D may be configured as an oxide layer, for example, a silicon oxide layer.

Further, the semiconductor device includes an array region 500 and a peripheral circuit region 510 according to different functions, the first region 201A and the second region 201B are located in the array region 500, and the third region 201C is located in the peripheral circuit region 510.

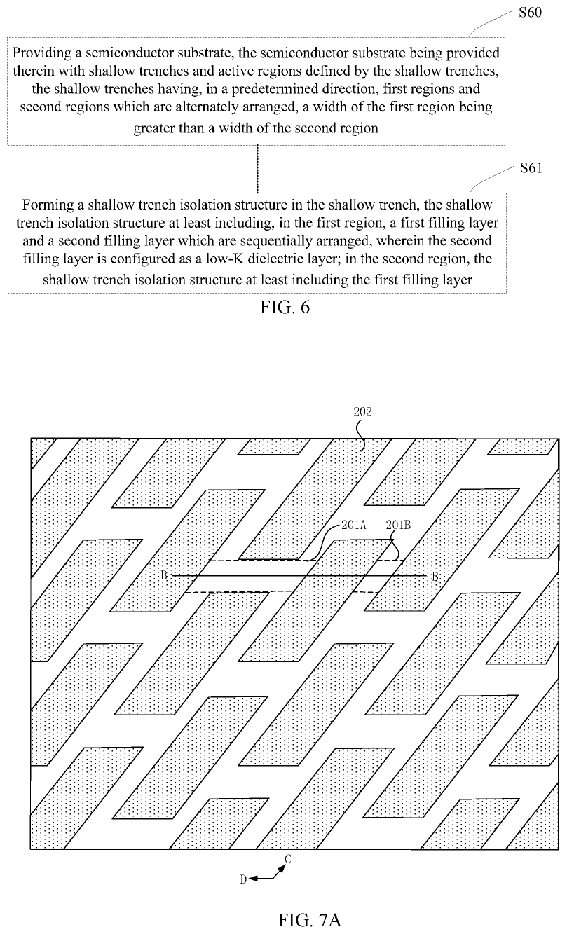

The present disclosure further provides a manufacturing method of the semiconductor device as described above. FIG. 6 is a schematic diagram of steps of a manufacturing method of a semiconductor device according to an embodiment of the present disclosure. Referring to FIG. 6, the manufacturing method includes the following steps: S60, providing a semiconductor substrate, the semiconductor substrate being provided therein with shallow trenches and active regions defined by the shallow trenches, the shallow trenches having, in a predetermined direction, first regions and second regions which are alternately arranged, a width of the first region being greater than a width of the second region; and step S61, forming a shallow trench isolation structure in the shallow trench, the shallow trench isolation structure at least including, in the first region, a first filling layer and a second filling layer which are sequentially arranged, wherein the second filling layer is configured as a low-K dielectric layer; in the second region, the shallow trench isolation structure at least including the first filling layer.

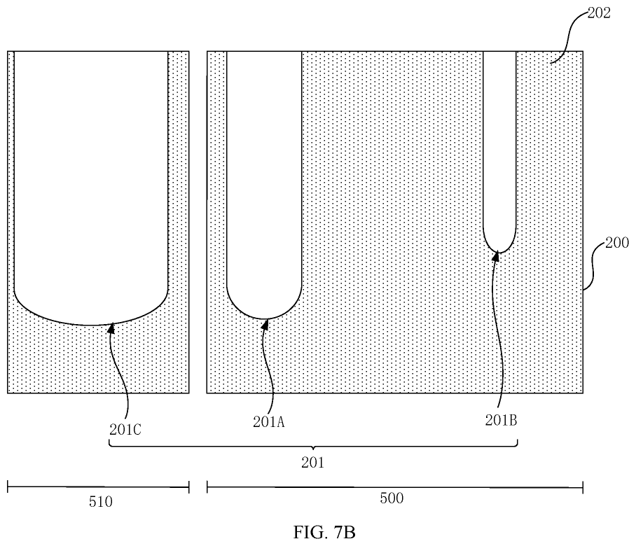

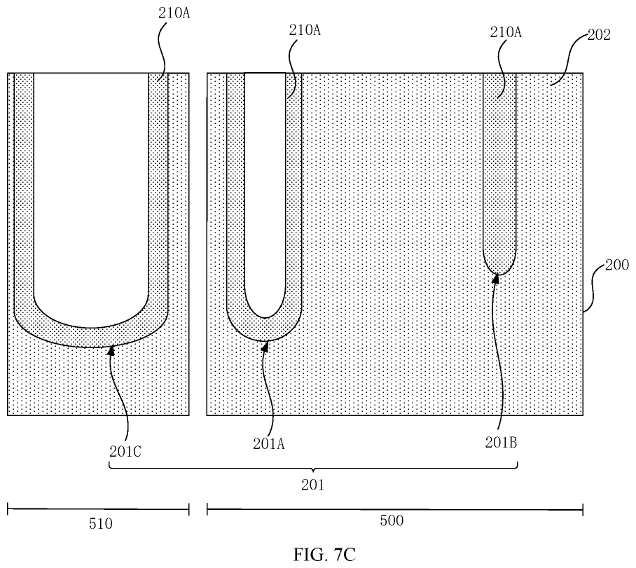

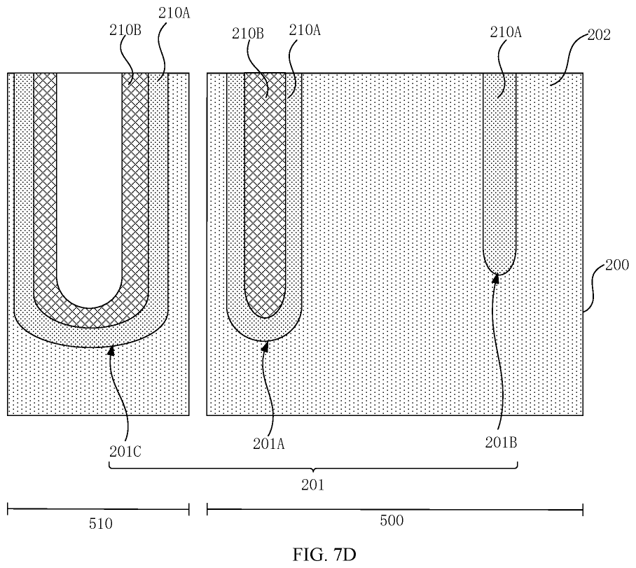

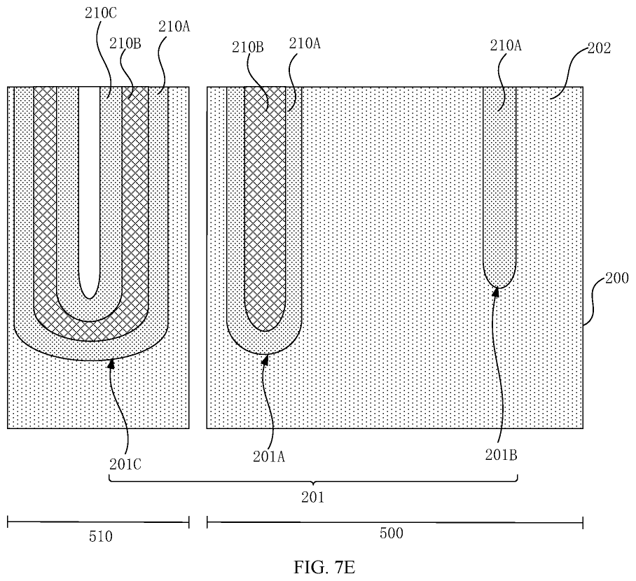

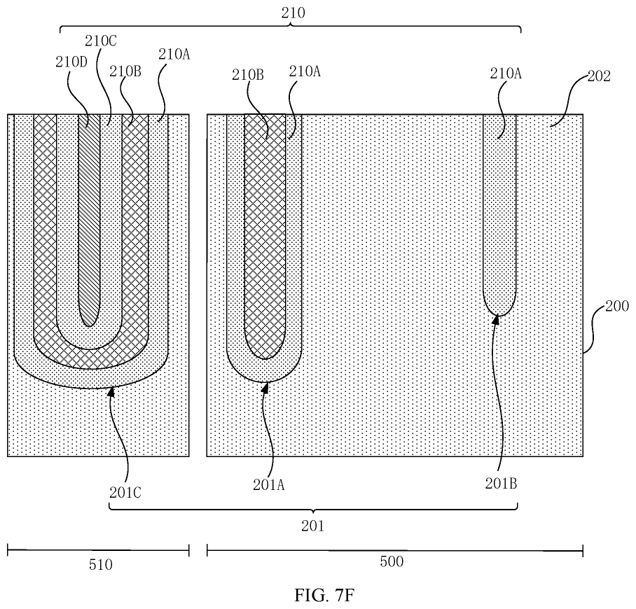

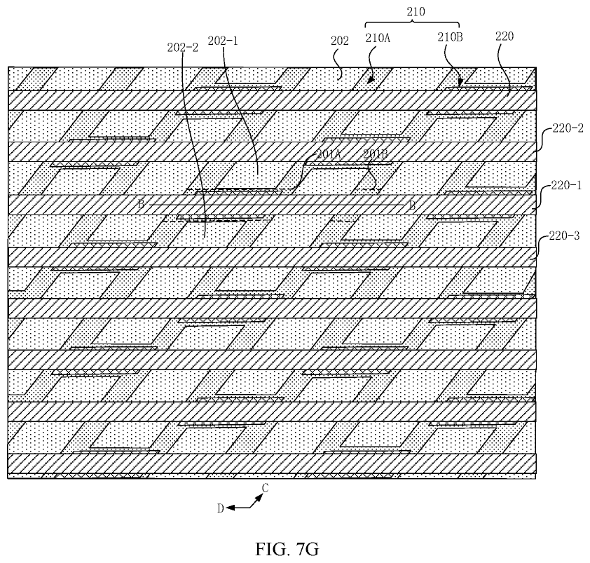

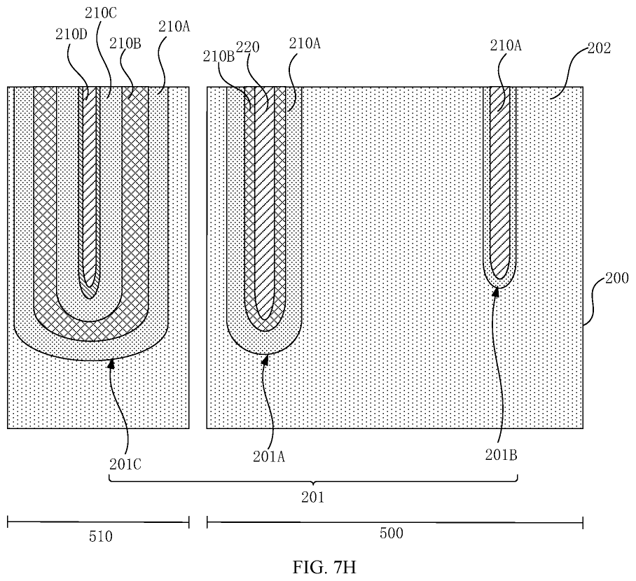

FIGS. 7A-7H are process diagrams of a manufacturing method of a semiconductor device according to an embodiment of the present disclosure.

Referring to step S60, FIG. 7A and FIG. 7B, where FIG. 7A is a top view and FIG. 7B is a schematic cross-sectional view taken along line BB in FIG. 7A, a semiconductor substrate 200 is provided; the semiconductor substrate 200 is provided therein with shallow trenches 201 and active regions 202 defined by the shallow trenches 201; in a predetermined direction, the shallow trenches 201 have first regions 201A and second regions 201B which are alternately arranged, and a width of the first region 201A is larger than a width of the second region 201B.

In this embodiment, the shallow trenches 201 are formed in the semiconductor substrate 200 by photolithography and etching processes, and a region between the shallow trenches 201 serves as the active region 202. The active region 202 extends along a set direction, i.e., Direction C, that is, the active region 202 extends in the Direction C.

In a predetermined direction (e.g., Direction D as shown in FIG. 7A), the first regions 201A and the second regions 201B are alternately arranged, and the width of the first region 201A is greater than the width of the second region 201B. In FIG. 7A, the first region 201A and the second region 201B are schematically encircled by dashed boxes.

Further, in this embodiment, the shallow trench 201 further includes a third region 201C, and a width of the third region 201C is greater than the width of the first region 201A.

Further, in this embodiment, the semiconductor device of the present disclosure includes an array region 500 and a peripheral circuit region 510 according to different functions. The first region 201A and the second region 201B are located in the array region 500, and the third region 201C is located in the peripheral circuit region 510. The peripheral circuit region 510 is not shown in FIG. 7A.

Referring to step S61 and FIGS. 7C to 7F, a shallow trench isolation structure 210 is formed in the shallow trench 201. In the first region 201A, the shallow trench isolation structure 210 at least includes a first filling layer 210A and a second filling layer 210B which are sequentially arranged, wherein the second filling layer 210B is configured as a low-K dielectric layer, and in the second region 201B, the shallow trench isolation structure at least includes the first filling layer 210A.

Further, in the third region 201C of the shallow trench 201, the shallow trench isolation structure 210 at least includes the first filling layer 210A, the second filling layer 210B, and the third filling layer 210C.

In this embodiment, in the first region 201A, the first filling layer 210A covers the sidewalls of the shallow trench 201, and the second filling layer 210B covers the sidewalls of the first filling layer 210A and fills up the shallow trench; in the second region 201B, the shallow trench isolation structure 210 has one layer, and the first filling layer 210A covers the sidewalls of the shallow trench 201 and fills up the shallow trench; in the third region 201C, the first filling layer 210A covers the sidewalls of the shallow trench 201, the second filling layer 210B covers the sidewalls of the first filling layer 210A, and the third filling layer 210A covers the sidewalls of the second filling layer 210B.

In this embodiment, since the width of the shallow trench 201 located in the third region 201C is quite different from the width of the shallow trench 201 located in the first region 201A, and after the third filling layer 210C is formed, a fourth filling layer 210D is formed in the shallow trench 201. The fourth filling layer 210D covers the third filling layer 210C and fills up the shallow trench 201.

The first filling layer 210A may be made of an oxide, such as silicon oxide; the second filling layer 210B is made of a low-K dielectric material, such as PSG, BPSG, and FSG; the third filling layer 210C may be made of a nitride, such as silicon nitride; the fourth filling layer 210D may be made of an oxide, such as silicon oxide.

The following specifically describes the step of forming the shallow trench isolation structure in this embodiment.

Referring to FIG. 7C, the first filling layer 210A is formed in the shallow trench 201. In the first region 201A, the first filling layer 210A covers the sidewalls of the shallow trench 201; in the second region 201B, the first filling layer 210A fills up the shallow trench; in the third region 201C, the first filling layer 210A covers the sidewalls of the shallow trench 201.

Referring to FIG. 7D, the second filling layer 210B is formed in the shallow trench 201. In the first region 201A, the second filling layer 210B covers the first filling layer 210A and fills up the shallow trench 201; in the second region 201B, the second filling layer 210B is not formed; in the third region 201C, the second filling layer 210B covers the first filling layer 210A.

Referring to FIG. 7E, the third filling layer 210C is formed in the shallow trench 201. In the first region 201A, the third filling layer 210C is not formed; in the second region 201B, the third filling layer 210C is not formed; in the third region 201C, the third filling layer 210C covers the second filling layer 210B.

Referring to FIG. 7F, the fourth filling layer 210D is formed in the shallow trench 201. In the first region 201A, the fourth filling layer 210D is not formed; in the second region 201B, the fourth filling layer 210D is not formed; in the third region 201C, the fourth filling layer 210D covers the third filling layer 210C and fills up the shallow trench 201.

In other embodiments of the present disclosure, if the fourth filling layer 210D is not formed, in the step shown in FIG. 2E and in the third region 201C, the third filling layer 210C fills up the shallow trench 201.

Further, after step S61, the manufacturing method further includes the following step of forming a plurality of wordlines 220, with reference to FIG. 7G and FIG. 7H, where FIG. 7G is a top view, and FIG. 7H is a schematic cross-sectional view taken along line BB in FIG. 7G. The wordlines 220 sequentially pass through the active region 202 and the shallow trench isolation structure 210 along the predetermined direction (Direction D).

The formation of the wordline 220 can be implemented by a conventional method in the art, and will not be repeated here.

According to the manufacturing method of the present disclosure, the second filling layer 210B (a low-K dielectric layer) is arranged in the first region 201B (i.e., the region through which the Passing WL passes) of the shallow trench, which can reduce the parasitic capacitance caused by the wordline and further reducing leakage current.

The above are only the preferred embodiments of the present disclosure. It should be noted that for those of ordinary skill in the art, without departing from the principle of the present disclosure, several improvements and modifications can be made, and these improvements and modifications also should be considered as falling within the protection scope of the present disclosure.

What is claimed is:

1. A semiconductor device, comprising:
a semiconductor substrate provided therein with shallow trenches and active regions defined by the shallow trenches, the shallow trenches having, in a predetermined direction, first regions and second regions which are alternately arranged, a width of the first region being greater than a width of the second region; and
a shallow trench isolation structure filled in the shallow trench, the shallow trench isolation structure at least comprising, in the first region, a first filling layer and a second filling layer which are sequentially arranged, wherein the second filling layer is configured as a low-K dielectric layer; in the second region, the shallow trench isolation structure at least comprising the first filling layer.

2. The semiconductor device according to claim 1, wherein in the first region, the first filling layer covers sidewalls of the shallow trench, and the second filling layer covers sidewalls of the first filling layer and fills up the shallow trench.

3. The semiconductor device according to claim 1, wherein in the second region, the first filling layer fills up the shallow trench.

4. The semiconductor device according to claim 1, wherein the first filling layer is configured as an oxide layer.

5. The semiconductor device according to claim 1, wherein a dielectric constant of the second filling layer is less than or equal to 4.

6. The semiconductor device according to claim 1, wherein in the predetermined direction, a width of the second filling layer is less than the width of the first region and greater than or equal to one third of the width of the first region.

7. The semiconductor device according to claim 1, wherein the shallow trench further comprises a third region, a width of the third region is greater than the width of the first region, and in the third region, the shallow trench isolation structure at least comprises the first filling layer, the second filling layer, and a third filling layer which are arranged sequentially.

8. The semiconductor device according to claim 7, wherein in the third region, the shallow trench isolation structure further comprises a fourth filling layer, and the fourth filling layer covers the third filling layer and fills up the shallow trench.

9. The semiconductor device according to claim 8, wherein the third filling layer is configured as a nitride layer, and the fourth filling layer is configured as an oxide layer.

10. The semiconductor device according to claim 7, comprising an array region and a peripheral circuit region, the first region and the second region being located in the array region, the third region being located in the peripheral circuit region.

11. The semiconductor device according to claim 1, further comprising a plurality of wordlines, the wordlines sequentially passing through the active region and the shallow trench isolation structure along the predetermined direction.

12. A manufacturing method of a semiconductor device, comprising:
providing a semiconductor substrate, the semiconductor substrate being provided therein with shallow trenches and active regions defined by the shallow trenches, the shallow trenches having, in a predetermined direction, first regions and second regions which are alternately arranged, a width of the first region being greater than a width of the second region; and
forming a shallow trench isolation structure in the shallow trench, the shallow trench isolation structure at least comprising, in the first region, a first filling layer and a second filling layer which are sequentially arranged, wherein the second filling layer is configured as a low-K dielectric layer; in the second region, the shallow trench isolation structure at least comprising the first filling layer.

13. The manufacturing method of a semiconductor device according to claim 12, wherein said forming the shallow trench isolation structure in the shallow trench further comprises:
forming a first filling layer in the shallow trench, the first filling layer covering sidewalls of the shallow trench in the first region and filling up the shallow trench in the second region; and
forming a second filling layer in the shallow trench, the second filling layer covering the first filling layer and filling up the shallow trench in the first region.

14. The manufacturing method of a semiconductor device according to claim 13, wherein the shallow trench further comprises a third region, and a width of the third region is greater than the width of the first region;
said forming the first filling layer in the shallow trench further comprises: in the third region, the first filling layer covering the sidewalls of the shallow trench;
said forming the second filling layer in the shallow trench further comprises: in the third region, the second filling layer covering the sidewalls of the first filling layer;
forming a third filling layer in the shallow trench, the third filling layer covering the second filling layer in the third region.

15. The manufacturing method of a semiconductor device according to claim 14, after said forming the third filling layer in the shallow trench, the method further comprising:
forming a fourth filling layer in the shallow trench, the fourth filling layer covering the third filling layer and filling up the shallow trench in the third region.

16. The manufacturing method of a semiconductor device according to claim 12, after said forming the shallow trench isolation structure in the shallow trench, the method further comprising:
forming a plurality of wordlines, the wordlines sequentially passing through the active region and the shallow trench isolation structure along the predetermined direction.
